(19) United States
(12) Patent Application Publication
(10) Pub. No.: US 2026/0026196 A1
(43) Pub. Date: Jan. 22, 2026

(54) Display Panel and Display Device

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Mingzhi Chai, Beijing (CN); Taofeng Xie, Beijing (CN); Yuanjie Xu, Beijing (CN); Zhuoan Li, Beijing (CN); Meng Li, Beijing (CN); Xingliang Xiao, Beijing (CN)

(21) Appl. No.: 18/859,402

(22) PCT Filed: Jan. 25, 2024
(86) PCT No.: PCT/CN2024/074113

§ 371 Date: Oct. 23, 2024

(51) Int. Cl. H10K 59/122; H10K 59/35

(52) U.S. Cl. CPC H10K 59/122; H10K 59/353

(57) ABSTRACT

A display panel includes at least one bending portion, sub-pixels and first spacers. The bending portion is bendable along a bending axis. The sub-pixels are arranged in rows and columns. The rows of sub-pixels each include at least two sub-pixels arranged in a first direction, and the columns of sub-pixels each include at least two sub-pixels arranged in a second direction. The first spacers are disposed between the sub-pixels and located at the bending portion. The first spacers are arranged in rows and columns. The rows of first spacers each include at least two first spacers arranged in the first direction, and the columns of first spacers each include at least two first spacers arranged in the second direction. A density of first spacers arranged in the first direction is less than a density of first spacers arranged in the second direction.

### CROSS-REFERENCE TO RELATED APPLICATION

This application is the United States national phase of International Patent Application No. PCT/CN2024/074113, filed Jan. 25, 2024, the disclosure of which is hereby incorporated by reference in its entirety.

### BACKGROUND OF THE INVENTION

### Field of the Invention

The present disclosure relates to the field of display technologies, and in particular, to a display panel and a display device.

### Description of Related Art

With the rapid development of display technologies, display devices have gradually spread in people's lives. Organic light-emitting diodes (OLEDs) are widely used in smart products such as mobile phones, televisions and notebook computers due to self-luminescence, low power consumption, wide viewing angle, fast response speed, high contrast, flexible display and other advantages.

### SUMMARY OF THE INVENTION

In an aspect, a display panel is provided. The display panel has a display area. The display panel includes at least one bending portion. The bending portion is bendable along a bending axis extending in a first direction. The display panel further includes a plurality of sub-pixels and a plurality of first spacers. The plurality of sub-pixels are arranged in a plurality of rows and a plurality of columns in the display area. The plurality of rows of sub-pixels each include at least two sub-pixels arranged in the first direction, and the plurality of columns of sub-pixels each include at least two sub-pixels arranged in a second direction. The first direction intersects the second direction.

The plurality of first spacers are disposed between the plurality of sub-pixels and located at the bending portion. The plurality of first spacers are arranged in a plurality of rows and a plurality of columns. The plurality of rows of first spacers each include at least two first spacers arranged in the first direction, and the plurality of columns of first spacers each include at least two first spacers arranged in the second direction. A density of first spacers arranged in the first direction is less than a density of first spacers arranged in the second direction.

In some embodiments, a number of sub-pixels between any two adjacent first spacers in each row of first spacers is greater than a number of sub-pixels between any two adjacent first spacers in each column of first spacers.

In some embodiments, at least four sub-pixels exist between any two adjacent first spacers in each row of first spacers, and at least two sub-pixels exist between any two adjacent first spacers in each column of first spacers.

In some embodiments, the display panel further includes non-bending portion(s), and the non-bending portion(s) are connected to the bending portion. The display panel further includes a plurality of second spacers. The plurality of second spacers are disposed between the plurality of sub-pixels and located at the non-bending portion. The plurality of second spacers are arranged in a plurality of rows and a plurality of columns. The plurality of rows of second spacers each include at least two second spacers arranged in the first direction, and the plurality of columns of second spacers each include at least two second spacers arranged in the second direction. A density of second spacers arranged in the first direction is less than or equal to a density of second spacers arranged in the second direction.

The density of the second spacers arranged in the first direction is greater than the density of the first spacers arranged in the first direction; and/or the density of the second spacers arranged in the second direction is greater than or equal to the density of the first spacers arranged in the second direction.

In some embodiments, a number of sub-pixels between any two adjacent second spacers in each row of second spacers is equal to a number of sub-pixels between any two adjacent second spacers in each column of second spacers.

In some embodiments, in the second direction and from a bending portion to a non-bending portion, the non-bending portion includes a plurality of sub-portions connected to each other. In two adjacent sub-portions, a sub-portion farther away from the bending portion is a first sub-portion, and a sub-portion closer to the bending portion is a second sub-portion.

A density of second spacers at the first sub-portion arranged in the first direction is greater than a density of second spacers at an adjacent second sub-portion arranged in the first direction; and/or a density of second spacers at the first sub-portion arranged in the second direction is greater than or equal to a density of second spacers at the adjacent second sub-portion arranged in the second direction.

In some embodiments, a sub-portion farthest away from the bending portion in the plurality of sub-portions is a third sub-portion, and remaining sub-portions are fourth sub-portions. At the third sub-portion, a number of sub-pixels between any two adjacent second spacers in each row of second spacers is equal to a number of sub-pixels between any two adjacent second spacers in each column of second spacers. And/or, at a fourth sub-portion, a number of sub-pixels between any two adjacent second spacers in each row of second spacers is greater than a number of sub-pixels between any two adjacent second spacers in each column of second spacers.

In some embodiments, the plurality of sub-pixels includes a plurality of red sub-pixels, a plurality of green sub-pixels and a plurality of blue sub-pixels. The plurality of red sub-pixels and the plurality of blue sub-pixels are arranged in an array of multiple rows and multiple columns. Each row of red sub-pixels and blue sub-pixels includes multiple red sub-pixels and multiple blue sub-pixels that are arranged alternately in the first direction, and each column of red sub-pixels and blue sub-pixels includes multiple red sub-pixels and multiple blue sub-pixels that are arranged alternately in the second direction. The plurality of green sub-pixels are arranged in an array of multiple rows and multiple columns, and a green sub-pixel is disposed between red sub-pixels and blue sub-pixels in each two rows and two columns arranged adjacent to each other.

In some embodiments, in two adjacent rows of first spacers, any first spacer in a row of first spacers is located between two adjacent first spacers in another row of first spacers.

In some embodiments, sub-pixels existing between any two first spacers that belong to different rows and are adjacent in the first direction have a same number.

In some embodiments, the display panel further includes a plurality of second spacers. In two adjacent rows of second spacers, any second spacer in a row of second spacers is located between two adjacent second spacers in another row of second spacers.

In some embodiments, sub-pixels existing between any two second spacers that belong to different rows and are adjacent in the first direction have a same number.

In some embodiments, geometric centers of orthographic projections of two adjacent first spacers in a same row on a reference plane are connected to form a first virtual connection line, and the first virtual connection line intersects the first direction. The reference plane is a plane defined by the first direction and the second direction. And/or, geometric centers of orthographic projections of two adjacent first spacers in a same column on the reference plane are connected to form a second virtual connection line, and the second virtual connection line intersects the second direction.

In some embodiments, the display panel further includes a plurality of second spacers. Geometric centers of orthographic projections of two adjacent second spacers in a same row on a reference plane are connected to form a third virtual connection line, and the third virtual connection line intersects the first direction. The reference plane is a plane determined by the first direction and the second direction. And/or, geometric centers of orthographic projections of two adjacent second spacers in a same column on the reference plane are connected to form a fourth virtual connection line, and the fourth virtual connection line intersects the second direction.

In some embodiments, the display panel further has a peripheral area surrounding the display area. The peripheral area includes four frame areas and four corner areas connecting the four frame areas. The four frame areas include a first frame area, a second frame area, a third frame area and a fourth frame area. In the first direction, the first frame area and the third frame area are located on opposite sides of the display area; and in the second direction, the second frame area and the fourth frame area are located on opposite sides of the display area.

The display panel further includes a voltage signal line and a plurality of third spacers. An end of the voltage signal line is located in a corner area at an end of the fourth frame area, and another end of the voltage signal line stops in a corner area at another end of the fourth frame area passing through the first frame area, the second frame area, the third frame area, and corner areas between the first frame area, the second frame area and the third frame area. The plurality of third spacers are disposed in the peripheral area. In the first frame area, the second frame area, the third frame area and the four corner areas, third spacers are disposed between the voltage signal line and the display area; and in the fourth frame area, third spacers are disposed between an edge of the display area and an edge of the fourth frame area.

In some embodiments, in any frame area or corner area, the plurality of third spacers include a plurality of middle spacers. The plurality of middle spacers are arranged in a plurality of rows and a plurality of columns. The plurality of rows of middle spacers each include at least two middle spacers arranged in the first direction, and the plurality of columns of middle spacers each include at least two middle spacers arranged in the second direction. In the first frame area and/or the third frame area, a row of middle spacers is disposed in a same row as a row of first spacers or a row of second spacers. And/or, in the second frame area and/or the fourth frame area, a column of middle spacers is disposed in a same column as a column of first spacers.

In some embodiments, in at least one frame area or corner area, the plurality of third spacers further include a plurality of peripheral spacers. The plurality of peripheral spacers are arranged in a row along a target boundary. In the first frame area, the second frame area, the third frame area and the four corner areas, the target boundary is a boundary of the voltage signal line proximate to the display area; and in the fourth frame area, the target boundary is a boundary of the fourth frame area away from the display area.

In some embodiments, a distance between a peripheral spacer and the target boundary is less than or equal to 130 μm.

In some embodiments, a distance between any third spacer and at least one third spacer is less than or equal to 130 μm; and/or a distance between at least one third spacer and an edge of the display area is less than or equal to 130 μm.

In another aspect, a display device is provided. The display device includes the display panel as described in any of the above embodiments and a circuit board. The circuit board is connected to the display panel.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display device, in accordance with some embodiments;

FIG. 2 is a structural diagram of another display device, in accordance with some embodiments;

FIG. 3 is a structural diagram of yet another display device, in accordance with some embodiments;

FIG. 4 is a structural diagram of yet another display device, in accordance with some embodiments;

FIG. 5 is a sectional view of the display apparatus in FIG. 1 taken along a section line A-A;

FIG. 6 is a top view of a display panel, in accordance with some embodiments;

FIG. 7 is a sectional view of a display panel, in accordance with some embodiments;

FIG. 8 is a partial enlargement view of a bending portion of a display panel, in accordance with some embodiments;

FIG. 9 is a diagram showing an arrangement of sub-pixels and spacers at a bending portion of a display panel, in accordance with some embodiments;

FIG. 10 is a diagram showing another arrangement of sub-pixels and spacers at a bending portion of a display panel, in accordance with some embodiments;

FIG. 11 is a diagram showing yet another arrangement of sub-pixels and spacers at a bending portion of a display panel, in accordance with some embodiments;

FIG. 12 is a diagram showing yet another arrangement of sub-pixels and spacers at a bending portion of a display panel, in accordance with some embodiments;

FIG. 13 is a diagram showing yet another arrangement of sub-pixels and spacers at a bending portion of a display panel, in accordance with some embodiments;

FIG. 14 is a diagram showing yet another arrangement of sub-pixels and spacers at a bending portion of a display panel, in accordance with some embodiments;

FIG. 15 is a diagram showing yet another arrangement of sub-pixels and spacers at a bending portion of a display panel, in accordance with some embodiments;

FIG. 16 is a diagram showing an arrangement of sub-pixels and spacers corresponding to a bending portion and a non-bending portion of a display panel, in accordance with some embodiments;

FIG. 17 is a diagram showing an arrangement of sub-pixels and spacers at a non-bending portion of a display panel, in accordance with some embodiments;

FIG. 18 is a diagram showing another arrangement of sub-pixels and spacers at a non-bending portion of a display panel, in accordance with some embodiments;

FIG. 19 is a diagram showing yet another arrangement of sub-pixels and spacers at a non-bending portion of a display panel, in accordance with some embodiments;

FIG. 20 is a diagram showing another arrangement of sub-pixels and spacers corresponding to a bending portion and a non-bending portion of a display panel, in accordance with some embodiments;

FIG. 21 is a diagram showing yet another arrangement of sub-pixels and spacers at a non-bending portion of a display panel, in accordance with some embodiments;

FIG. 22 is a diagram showing yet another arrangement of sub-pixels and spacers at a non-bending portion of a display panel, in accordance with some embodiments;

FIG. 23 is a diagram showing yet another arrangement of sub-pixels and spacers at a non-bending portion of a display panel, in accordance with some embodiments;

FIG. 24 is a diagram showing yet another arrangement of sub-pixels and spacers at a non-bending portion of a display panel, in accordance with some embodiments;

FIG. 25 is a diagram showing an arrangement of sub-pixels and spacers in a frame area of a display panel, in accordance with some embodiments; and

FIG. 26 is a diagram showing an arrangement of sub-pixels and spacers in a corner area of a display panel, in accordance with some embodiments.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

In the description of the present disclosure, orientations or positional relationships indicated by the terms such as “center”, “upper”, “lower”, “left”, “right”, “inner”, “outer” and the like may be based on orientations or positional relationships shown in the drawings, or based on a sequence of process steps formed, which are merely to facilitate and simplify the description of the present disclosure, and are not to indicate or imply that the devices or elements referred to must have a particular orientation, or be constructed or operated in a particular orientation. Therefore, these terms should not be construed as limitations on the present disclosure.

In the contents of the present disclosure, the meanings of the terms “on”, “above” and “over” should be interpreted in a broadest manner, so that the term “on” not only means “directly on something”, but also includes the meaning of “on something” with intervening features or layers therebetween, and the term “above” or “over” not only means “above” or “over” something, but also includes the meaning of “above” or “over” something without intervening features or layers therebetween (i.e., directly on something).

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “connected” and derivatives thereof may be used. The term “connection” should be understood in a broad sense. For example, the “connection” may be a mechanical connection or an electrical connection; it may be a fixed connection, a detachable connection, or of an integrated structure; it may be a direct connection, an indirect connection by an intermediate medium, or an internal communication between two elements. Specific meanings of the above terms in the article may be understood by a person of ordinary skill in the art depending on specific situations.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°, and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in a device, and are not intended to limit the scope of the exemplary embodiments.

In the embodiments of the present disclosure, the adopted transistors may be thin film transistors (TFTs), field effect transistors (e.g., metal oxide semiconductor transistors (MOS transistors)) or other switching devices with same characteristics. The embodiments of the present disclosure will all be described by taking the thin film transistors as an example.

The term “opposite to” means that a first element may be directly or indirectly opposite to a second element. In a case where a third element is provided between the first element and the second element, the first element and the second element may be understood as being indirectly opposite to each other although still opposite to each other.

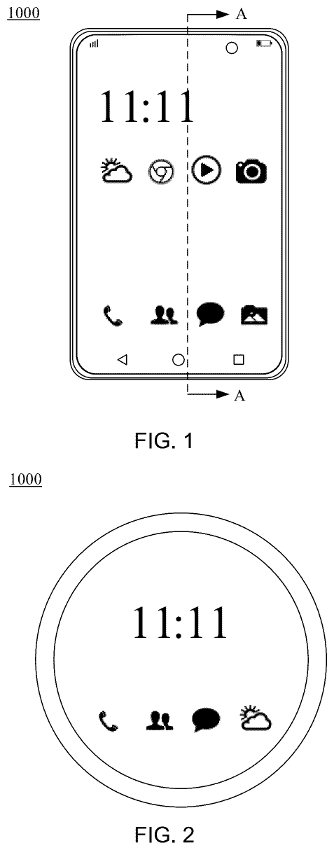

As shown in FIG. 1, some embodiments of the present disclosure provide a display device 1000, and the display device 1000 may be any device that displays images whether in motion (such as a video) or fixed (such as a still image), and regardless of text or image.

For example, the display device 1000 may be any product or component having a display function such as a television, a notebook computer, a tablet computer, a mobile phone, a personal digital assistant (PDA), a navigator, a car display, a flight display, a wearable device, a virtual reality (VR) device, a projector, or an electronic billboard or sign.

For example, as shown in FIG. 1, the display device 1000 may be a portable display product; for example, the display device 1000 is a mobile phone shown in FIG. 1. As another example, referring to FIG. 2, the display device 1000 may be a wearable device; for example, the display device 1000 is a watch shown in FIG. 2.

It will be noted that, depending on different application scenarios, a display surface of the display device 1000 may be in a shape of any of a circular, an elliptical, a polygonal or an irregular shape, which is not specifically limited in the embodiments of the present disclosure.

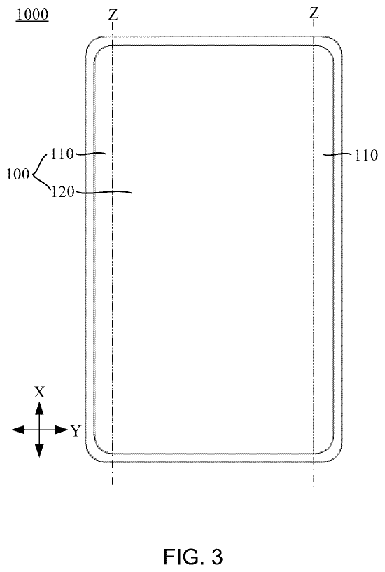

In some embodiments, as shown in FIG. 3, the display device 1000 may be a curved display device. The display device 1000 includes a display panel 100. The display panel 100 may, for example, include two bending portions 110 disposed oppositely and a non-bending portion 120 located between the two bending portions 110. Each bending portion 110 may be bendable along a bending axis Z extending in a first direction X. The bending portion 110 is a portion of the display panel 100 that may be bent, and the non-bending portion 120 is a portion of the display panel 100 that is not bent.

It will be noted that the display panel 100 may alternatively include only one bending portion 110 and does not include the non-bending portion 120, that is, the display surface of the display panel 100 is a continuous curved surface without a flat surface, which is not specifically limited in the embodiments of the present disclosure.

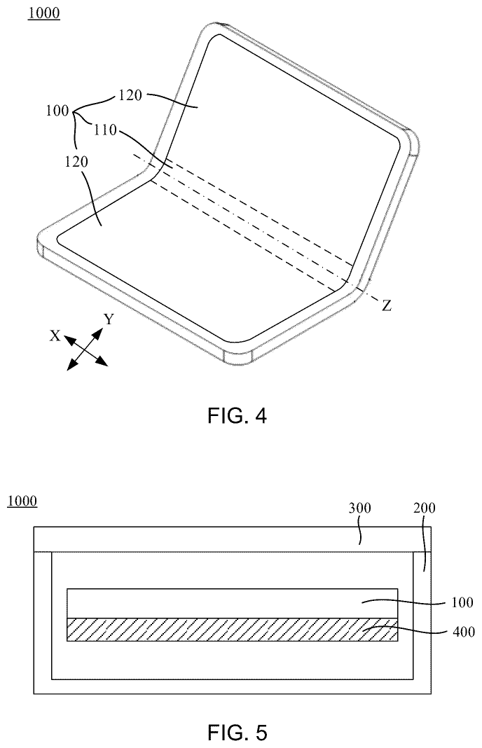

In some other embodiments, as shown in FIG. 4, the display device 1000 may be a foldable display device. The display device 1000 includes a display panel 100. The display panel 100 may, for example, include two non-bending portions 120 disposed oppositely and a bending portion 110 located between the two non-bending portions 120. The bending portion 110 may be bent along a bending axis Z extending in a first direction X, so that surfaces at the same side of the two non-bending portions 120 may be fitted.

Some embodiments of the present disclosure will be exemplarily described below by taking an example of the display device 1000 being a foldable display device, but implementations of the present disclosure are not limited thereto, and any other display device 1000 including bending portion(s) 110 may also be considered, as long as the same technical concept is applied.

In some embodiments, as shown in FIG. 5, the display device 1000 may further include a housing 200, a cover plate 300, a circuit board 400 and other electronic components. The display panel 100 and the circuit board 400 may be disposed inside the housing 200.

For example, as shown in FIG. 5, the housing 200 may be of a box-shaped structure with an opening. The display panel 100 and the circuit board 400 may be provided in the housing 200, and the cover plate 300 is provided on a surface of the display panel 100 for displaying the image and is located at the opening of the housing 200.

It will be understood that the type of the display panel 100 varies, which may be set according to actual needs.

For example, the display panel 100 is an organic light-emitting diode (OLED) display panel, a quantum dot light-emitting diode (QLED) display panel, or the like, which is not specifically limited in the embodiments of the present disclosure.

Some embodiments of the present disclosure will be exemplarily described below by taking an example of the display panel 100 being an OLED display panel, but implementations of the present disclosure are not limited thereto, and any other display panel 100 may also be considered, as long as the same technical concept is applied.

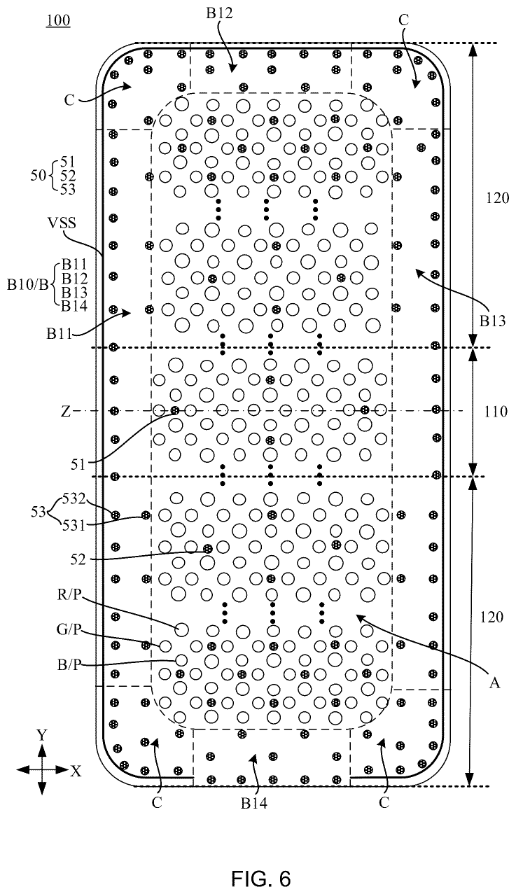

In some embodiments, as shown in FIG. 6, the display panel 100 has a display area A and a peripheral area B disposed on at least one side of the display area A. The display area A is an area for displaying images and is configured to be provided with a plurality of sub-pixels P therein. The peripheral area B is an area where no image is displayed thereon, and the peripheral area B is configured to be provided therein with a display driver circuit, for example, a gate driver circuit and a source driver circuit.

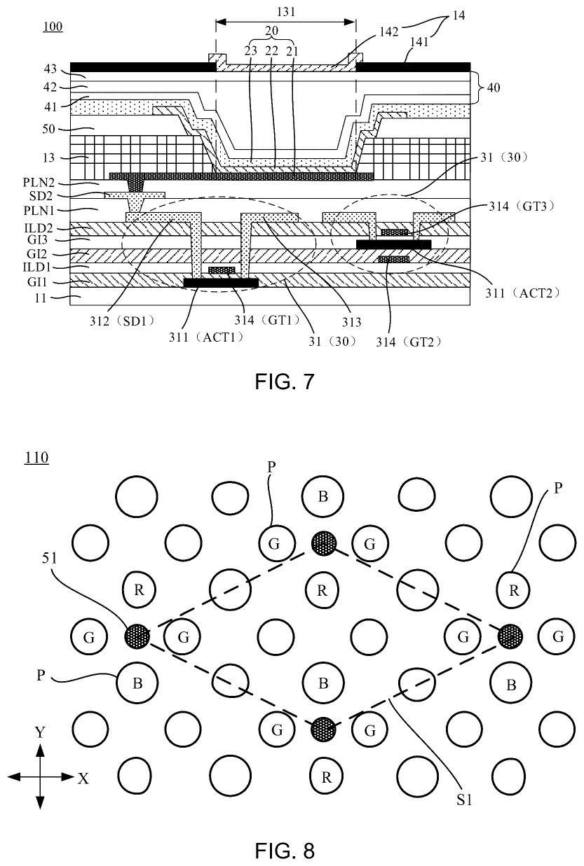

For example, referring to FIGS. 6 and 7, the display panel 100 includes a substrate 11 and a plurality of sub-pixels P disposed on a side of the substrate 11 and located in the display area A.

As shown in FIG. 6, the plurality of sub-pixels P may be arranged in a plurality of rows and a plurality of columns in the display area A. The plurality of rows of sub-pixels P each include at least two sub-pixels P arranged in the first direction X, and the plurality of columns of sub-pixels P each include at least two sub-pixels P arranged in a second direction Y. For example, each row of sub-pixels P includes at least two sub-pixels P arranged in the first direction X, and each column of sub-pixels P includes at least two sub-pixels P arranged in the second direction Y. The first direction X intersects with the second direction Y. For example, the first direction X is perpendicular to the second direction Y.

Some embodiments of the present disclosure will be exemplarily described below by taking an example of the first direction X being perpendicular to the second direction Y, but implementations of the present disclosure are not limited thereto.

In addition, the plurality of sub-pixels P may include, for example, a plurality of sub-pixels P with different luminous colors, and the plurality of sub-pixels P with different luminous colors interact with each other to achieve full-color display. For example, the plurality of sub-pixels P include red sub-pixels R with a luminous color of red, blue sub-pixels B with a luminous color of blue, and green sub-pixels G with a luminous color of green.

It can be understood that when full-color display is implemented, the arrangement of the red sub-pixels R, the blue sub-pixels B and the green sub-pixels G is not unique.

For example, as shown in FIG. 6, a plurality of red sub-pixels R and a plurality of blue sub-pixels B are arranged in an array of multiple rows and multiple columns, each row of red sub-pixels R and blue sub-pixels B includes multiple red sub-pixels R and multiple blue sub-pixels B that are arranged alternately in the first direction X, and each column of red sub-pixels R and blue sub-pixels B includes multiple red sub-pixels R and multiple blue sub-pixels B that are arranged alternately in the second direction Y. A plurality of green sub-pixels G are arranged in an array of multiple rows and multiple columns, and a green sub-pixel G is provided between red and blue sub-pixels R and B in each two rows and two columns arranged adjacent to each other. In this case, the arrangement of the red sub-pixel R, the blue sub-pixel B and the green sub-pixel G is first arrangement. The red sub-pixel R, the blue sub-pixel B and the green sub-pixel G are arranged in the first arrangement, and the display image is rather delicate and the display effect is relatively good.

It will be noted that geometric centers of sub-pixels P in the same row may be distributed on a plurality of straight lines that are parallel, and the first direction X is parallel to the straight lines; and geometric centers of sub-pixels P in the same column may be distributed on a plurality of straight lines that are parallel, and the second direction Y is parallel to the straight lines.

Some embodiments of the present disclosure will be exemplarily described below by taking an example where the plurality of sub-pixels P include red sub-pixels R, blue sub-pixels B and green sub-pixels G that are arranged in the first arrangement. However, implementations of the present disclosure are not limited thereto, and any other arrangements may also be considered as long as the same technical concept is applied.

In some embodiments, referring to FIGS. 6 and 7, the sub-pixel P includes a light-emitting device 20 and a pixel circuit 30. The pixel circuit 30 includes a plurality of transistors 31. The transistor 31 includes an active layer 311, a source 312, a drain 313 and a gate 314, and the source 312 and the drain 313 are each in contact with the active layer 311. The light-emitting device 20 includes a first electrode 21, a light-emitting functional layer 22 and a second electrode 23, and the first electrode 21 is electrically connected to a source 312 or a drain 313 of a transistor 31. FIG. 7 illustrates an example in which the first electrode 21 is electrically connected to the source 312 of the transistor 31.

It will be noted that the source 312 and the drain 313 may be interchanged, that is, a character “312” in FIG. 7 represents the drain, and a character “313” in FIG. 7 represents the source.

It will be understood that the film layer structure for forming the pixel circuits 30 in the display panel 100 is not unique. For example, as shown in FIG. 7, in a direction perpendicular to the substrate 11 and toward the light-emitting devices 20, the display panel 100 includes a first semiconductor layer ACT1, a first gate insulating layer Gl1, a first gate conductive layer GT1, a first interlayer insulating layer ILD1, a second gate conductive layer GT2, a second gate insulating layer GI2, a second semiconductor layer ACT2, a third gate insulating layer GI3, a third gate conductive layer GT3, a second interlayer insulating layer ILD2, a first source-drain conductive layer SD1, a first planarization layer PLN1, a second source-drain conductive layer SD2 and a second planarization layer PLN2 that are provided sequentially.

It will be noted that depending on different structures of the pixel circuit 30 and requirements of product design, the numbers of semiconductor layers, conductive layers and insulating layers may increase or decrease accordingly, which is not specifically limited in the embodiments of the present disclosure.

In some embodiments, referring to FIG. 7, the display panel 100 further includes an encapsulation layer 40, and the encapsulation layer 40 covers the light-emitting devices 20 to reduce the risk of failure of the light-emitting devices 20 caused by erosion of moisture and oxygen.

For example, as shown in FIG. 7, the encapsulation layer 40 may include a first inorganic encapsulation layer 41, an organic encapsulation layer 42 and a second inorganic encapsulation layer 43 that are stacked sequentially. The organic encapsulation layer 42 is located on a side of the first inorganic encapsulation layer 41 away from the light-emitting devices 20.

In some embodiments, referring to FIG. 7, the display panel 100 further includes a pixel defining layer 13 and a plurality of spacers 50. The pixel defining layer 13 defines a plurality of pixel openings 131. A light-emitting device 20 is located in a pixel opening 131. The plurality of spacers 50 are disposed between the pixel defining layer 13 and the encapsulation layer 40 and are each located in a region between the plurality of light-emitting devices 20. In this way, during a process of manufacturing the display panel 100, the spacers 50 may play a role in supporting a mask, so as to reduce scratches caused by direct contact between the mask and the pixel defining layer 13 or between the mask and the light-emitting devices 20, thereby affecting the display effect.

A distance between a spacer 50 and a pixel opening 131 may be, for example, greater than or equal to 10 μm, so as to avoid a decrease in light extraction efficiency caused by blocking of the light exit from the light-emitting device 20 by the spacer 50.

It will be noted that the spacer 50 may be in any shape of a prism, a cylinder, a pyramid, a cone, a hemisphere, a pyramid frustum, or a truncated cone, which is not specifically limited in the embodiments of the present disclosure.

In some related arts, spacers are evenly arranged in the display area of the display panel, and a distance between two adjacent spacers arranged in a direction (the first direction) parallel to the bending axis is equal to a distance between two adjacent spacers arranged in a direction (the second direction) perpendicular to the bending axis, so as to achieve a good supporting effect. That is, a density of spacers arranged in a direction parallel to the bending axis is equal to a density of spacers arranged in a direction perpendicular to the bending axis.

It will be noted that the density of the spacers arranged in the first direction may be understood as the number of the spacers in a row arranged in the first direction at a set length, and the density of the spacers arranged in the second direction may be understood as the number of the spacers in a column arranged in the second direction at a set length.

However, in a region at the bending portion and proximate to the bending portion, the closer the spacer is to the bending axis, the greater the compressive stress applied to an edge of the spacer. The edge of the spacer refers to an edge of a surface of an end of the spacer away from the substrate. When the compressive stress at the edge of the spacer accumulates to a certain extent, stress release will occur. The stress release process will cause an adjacent insulating film layer (e.g., the first inorganic packaging layer) to crack, resulting in erosion of the light-emitting device by moisture and oxygen along the cracked gap and causing the light-emitting device to fail.

In light of this, some embodiments of the present disclosure provide a display panel 100. Referring to FIGS. 6, 8 and 9, the display panel 100 includes a plurality of first spacers 51, and the plurality of first spacers 51 are disposed between the plurality of sub-pixels P and located at the bending portion 110.

The plurality of first spacers 51 are arranged in a plurality of rows and a plurality of columns. The plurality of rows of first spacers 51 each include at least two first spacers 51 arranged in the first direction X, and the plurality of columns of first spacers 51 each include at least two first spacers 51 arranged in the second direction Y. For example, each row of first spacers 51 includes at least two first spacers 51 arranged in the first direction X, and each column of first spacers 51 includes at least two first spacers 51 arranged in the second direction Y. Moreover, the density of the first spacers 51 arranged in the first direction X is less than the density of the first spacers 51 arranged in the second direction Y.

It will be understood that the closer the first spacer 51 is to the bending axis Z, the greater the compressive stress applied to the edge of the first spacer 51, and the greater the risk of stress release. Based on this, by reducing the density of the first spacers 51 arranged in the first direction X and increasing the density of the first spacers 51 arranged in the second direction Y, the number of the first spacers 51 with a relatively great risk of stress release may be reduced in a case where the total density of the first spacers 51 at the bending portion 110 is kept unchanged or slightly reduced, that is, in a case where the first spacers 51 provide a good support for the mask used in the process, thereby reducing stress release points, reducing the risk of cracking of the insulating film layer adjacent to the first spacers 51 (e.g., the first inorganic encapsulation layer 41 in FIG. 7), reducing the risk of failure of the light-emitting devices 20 (referring to FIG. 7), and improving product yield.

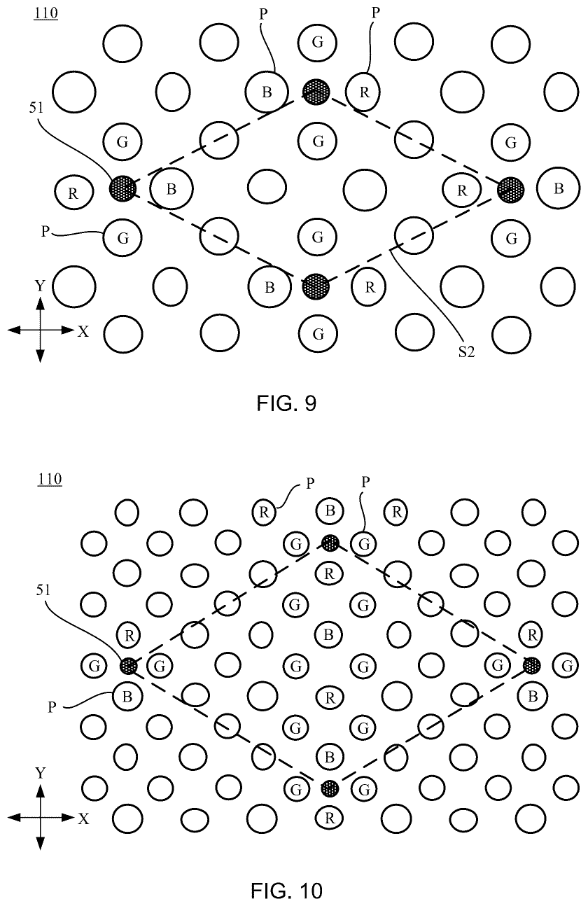

In some embodiments, referring to FIGS. 8 and 9, the number of sub-pixels P between any two adjacent first spacers 51 in each row of first spacers 51 is greater than the number of sub-pixels P between any two adjacent first spacers 51 in each column of first spacers 51.

Based on this, by increasing a distance between adjacent first spacers 51 in the first direction X and reducing a distance between first spacers 51 arranged in the second direction Y, the number of the first spacers 51 with a relatively great risk of stress release may further be reduced in a case where a supported area of four adjacent first spacers 51 (two first spacers 51 arranged in the first direction X and two first spacers 51 arranged in the second direction Y) remains unchanged or increases slightly, that is, in a case where the first spacers 51 provide a good support for the mask used in the process, thereby further reducing stress release points, reducing the risk of cracking of the insulating film layer adjacent to the first spacers 51 (e.g., the first inorganic encapsulation layer 41), reducing the risk of failure of the light-emitting devices 20 (referring to FIG. 7), and improving product yield.

For example, as shown in FIGS. 9, 10, 11 and 12, there are at least four sub-pixels P between any two adjacent first spacers 51 in each row of first spacers 51, and there are at least two sub-pixels P between any two adjacent first spacers 51 in each column of the first spacers 51.

For example, as shown in FIG. 9, there are four sub-pixels P between any two adjacent first spacers 51 in each row of first spacers 51, and there are two sub-pixels P between any two adjacent first spacers 51 in each column of the first spacers 51.

For example, as shown in FIG. 10, there are six sub-pixels P between any two adjacent first spacers 51 in each row of first spacers 51, and there are four sub-pixels P between any two adjacent first spacers 51 in each column of the first spacers 51.

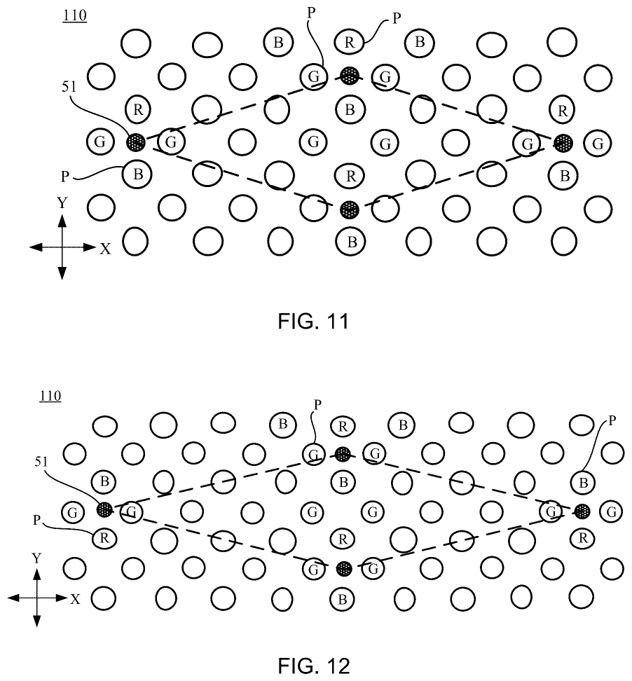

As another example, as shown in FIG. 11, there are six sub-pixels P between any two adjacent first spacers 51 in each row of first spacers 51, and there are two sub-pixels P between any two adjacent first spacers 51 in each column of the first spacers 51.

As another example, as shown in FIG. 12, there are eight sub-pixels P between any two adjacent first spacers 51 in each row of first spacers 51, and there are two sub-pixels P between any two adjacent first spacers 51 in each column of the first spacers 51.

Some embodiments of the present disclosure will be exemplarily described below by taking an example where there are four sub-pixels P between any two adjacent first spacers 51 in each row of first spacers 51, and there are two sub-pixels P between any two adjacent first spacers 51 in each column of the first spacers 51, but implementations of the present disclosure are not limited thereto.

Based on the fact that the arrangement of the plurality of sub-pixels P is the first arrangement, the first spacers 51 in two adjacent rows may be disposed in a staggered manner or located in the same column.

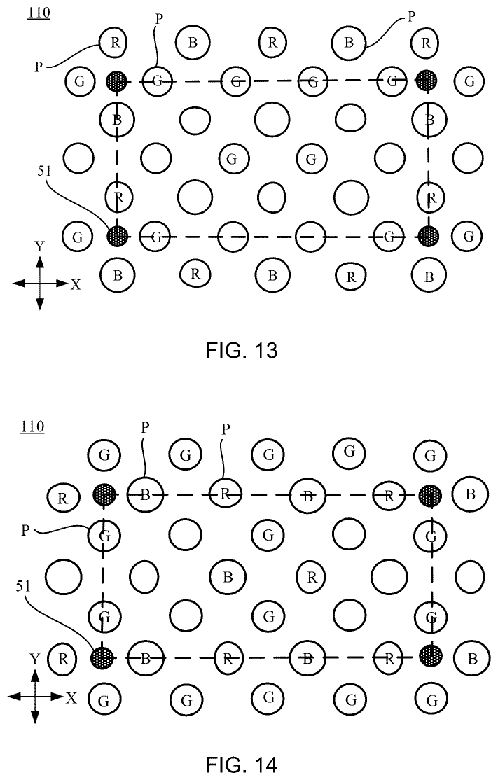

In some embodiments, referring to FIGS. 13 and 14, in two adjacent rows of first spacers 51, any first spacer 51 in a row of first spacers 51 is located in the same column as a first spacer 51 in another row of first spacers 51. That is, four first spacers 51 arranged in two adjacent rows and two adjacent columns constitute a minimum repeating unit, and a line connecting geometric centers of the four first spacers 51 is roughly in a shape of a rectangle.

For example, as shown in FIG. 13, in the first direction X, the first spacer 51 is located between two adjacent green sub-pixels G; in the second direction Y, the first spacer 51 is located between a red sub-pixel R and a blue sub-pixel B that are adjacent. In a case where any first spacer 51 in a row of first spacers 51 is located in the same column as a first spacer 51 in another row of first spacers 51, there is a row of green sub-pixels G between every two adjacent rows of first spacers 51, and there is no first spacer 51 provided between the green sub-pixels G.

For example, as shown in FIG. 14, in the first direction X, the first spacer 51 is located between a red sub-pixel R and a blue sub-pixel B; in the second direction Y, the first spacer 51 is located between two adjacent green sub-pixels G. In a case where any first spacer 51 in a row of first spacers 51 is located in the same column as a first spacer 51 in another row of first spacers 51, there is a row of red sub-pixels R and blue sub-pixels B arranged alternately between every two adjacent rows of first spacers 51, and there is no first spacer 51 provided between the red sub-pixel R and the blue sub-pixel B.

In some other embodiments, referring to FIGS. 8 and 9, in two adjacent rows of first spacers 51, in the first direction X, any first spacer 51 in a row of first spacers 51 is located between two adjacent first spacers 51 in another row of first spacers 51. That is, the two adjacent rows of first spacers 51 are disposed in a staggered manner.

For example, as shown in FIG. 8, in the first direction X, the first spacer 51 is located between two adjacent green sub-pixels G; in the second direction Y, the first spacer 51 is located between a red sub-pixel R and a blue sub-pixel B that are adjacent. In a case where two adjacent rows of first spacers 51 are disposed in a staggered manner, in each row of green sub-pixels G, there is a first spacer 51 provided between two adjacent green sub-pixels G.

On this basis, there are the same number of sub-pixels P between any two first spacers 51 that belong to different rows and are adjacent in the first direction X, so that the force for supporting the mask is dispersed rather evenly, thereby reducing the risk of cracking of the adjacent insulating film layer caused by stress release at the edge of the first spacer 51.

For example, as shown in FIG. 8, in two adjacent rows of first spacers 51, there are two green sub-pixels G between a first spacer 51 in a row of first spacers 51 and each of two first spacers 51 adjacent in the first direction X in another row of first spacers 51.

In a case where a line connecting a geometric center of the first spacer 51 and a geometric center of the adjacent sub-pixel P is approximately parallel to the first direction X or approximately parallel to the second direction Y, geometric centers of two first spacers 51 in a column and geometric centers of two first spacers 51 located between the two first spacers 51 and adjacent to the two first spacers 51 are connected to form a shape, which is a first shape S1, and the first shape is a rhombus. In this way, the force for supporting the mask may further be dispersed rather evenly, thereby further reducing the risk of cracking of the adjacent insulating film layer caused by stress release at the edge of the first spacer 51. It will be noted that an acceptable range of deviation of the approximate parallelism may be, for example, a deviation within 5°.

For example, as shown in FIG. 9, in the first direction X, the first spacer 51 is located between a red sub-pixel R and a blue sub-pixels B that are adjacent; in the second direction Y, the first spacer 51 is located between two adjacent green sub-pixels G. In a case where two adjacent rows of first spacers 51 are disposed in a staggered manner, in each row of red sub-pixels R and blue sub-pixels B arranged alternately, there is a first spacer 51 provided between a red sub-pixel R and a blue sub-pixel B that are adjacent.

On this basis, there are the same number of sub-pixels P between any two first spacers 51 that belong to different rows and are adjacent in the first direction X, so that the force for supporting the mask is dispersed rather evenly, thereby reducing the risk of cracking of the adjacent insulating film layer caused by stress release at the edge of the first spacer 51.

For example, as shown in FIG. 9, in two adjacent rows of first spacers 51, there is a red sub-pixel R and a blue sub-pixel B between a first spacer 51 in a row of first spacers 51 and each of two first spacers 51 adjacent in the first direction X in another row of first spacers 51.

In a case where a line connecting a geometric center of the first spacer 51 and a geometric center of the adjacent sub-pixel P is approximately parallel to the first direction X or approximately parallel to the second direction Y, geometric centers of two first spacers 51 in a column and geometric centers of two first spacers 51 located between the two first spacers 51 and adjacent to the two first spacers 51 are connected to form a shape, which is a second shape S2, and the second shape S2 is a rhombus. In this way, the force for supporting the mask may further be dispersed rather evenly, thereby further reducing the risk of cracking of the adjacent insulating film layer caused by stress release at the edge of the first spacer 51. It will be noted that an acceptable range of deviation of the approximate parallelism may be, for example, a deviation within 5°.

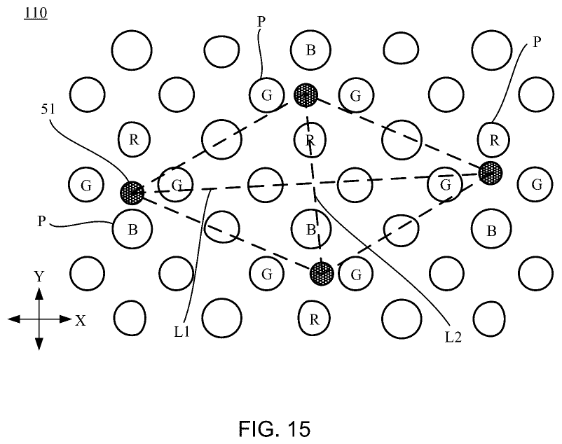

In some embodiments, referring to FIG. 15, geometric centers of orthographic projections of two adjacent first spacers 51 in the same row on the reference plane are connected to form a first virtual connection line L1, and the first virtual connection line L1 intersects the first direction X. And/or, geometric centers of orthographic projections of two adjacent first spacers 51 in the same column on the reference plane are connected to form a second virtual connection line L2, and the second virtual connection line L2 intersects the second direction Y. The reference plane is a plane defined by the first direction X and the second direction Y.

In this case, in first spacers 51 in the same row and/or the same column, geometric centers of two adjacent first spacers 51 are staggered, so that the supporting force for the supporting mask may be dispersed rather evenly, and thus the first spacers 51 may provide a rather good supporting effect. Moreover, in the first spacers 51 in the same row, the geometric centers of two adjacent first spacers 51 are staggered, and thus the compressive stress applied to the edge of the first spacer 51 during bending may also be reduced, thereby reducing the risk of cracking of the adjacent insulating film layer caused by stress release at the edge of the first spacer 51.

In some embodiments, referring to FIGS. 6, 16 and 17, the display panel 100 further includes non-bending portions 120, and the non-bending portion 120 is connected to the bending portion 110. On this basis, the display panel 100 further includes a plurality of second spacers 52, and the plurality of second spacers 52 are disposed between the plurality of sub-pixels P and located at the non-bending portions 120.

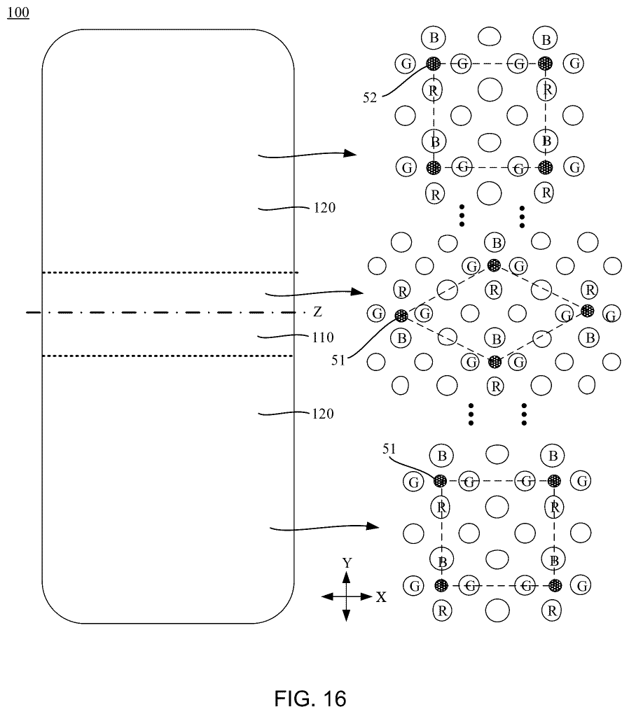

The plurality of second spacers 52 are arranged in a plurality of rows and a plurality of columns. The plurality of rows of second spacers 52 each include at least two second spacers 52 arranged in the first direction X, and the plurality of columns of second spacers 52 each include at least two second spacers 52 arranged in the second direction Y. For example, each row of second spacers 52 includes at least two second spacers 52 arranged in the first direction X, and each column of second spacers 52 includes at least two second spacers 52 arranged in the second direction Y. Moreover, the density of the second spacers 52 arranged in the first direction X is greater than the density of the first spacers 51 arranged in the first direction X; and/or the density of the second spacers 52 arranged in the second direction Y is greater than or equal to the density of the first spacers 51 arranged in the second direction Y. FIG. 16 illustrates an example in which the density of the second spacers 52 arranged in the first direction X is greater than the density of the first spacers 51 arranged in the first direction X, and the density of the second spacers 52 arranged in the second direction Y is equal to the density of the first spacers 51 arranged in the second direction Y.

It will be understood that the bending stress of the bending portion 110 is greater than the bending stress of the non-bending portion 120. Based on this, compared with the bending portion 110, the density of the second spacers 52 at the non-bending portion 120 arranged in the first direction X may increase; and the density of the second spacers 52 at the non-bending portion 120 arranged in the second direction Y may increase or remain unchanged. The specific selection may be made according to actual conditions. In this case, the density of arrangement of the second spacers 52 may increase, the support area for the mask may increase, and the support effect of the spacers 50 on the mask may be improved, thereby reducing the risk of static electricity release caused by a relatively small distance between the mask and the first electrode 21 of the light-emitting device 20 below.

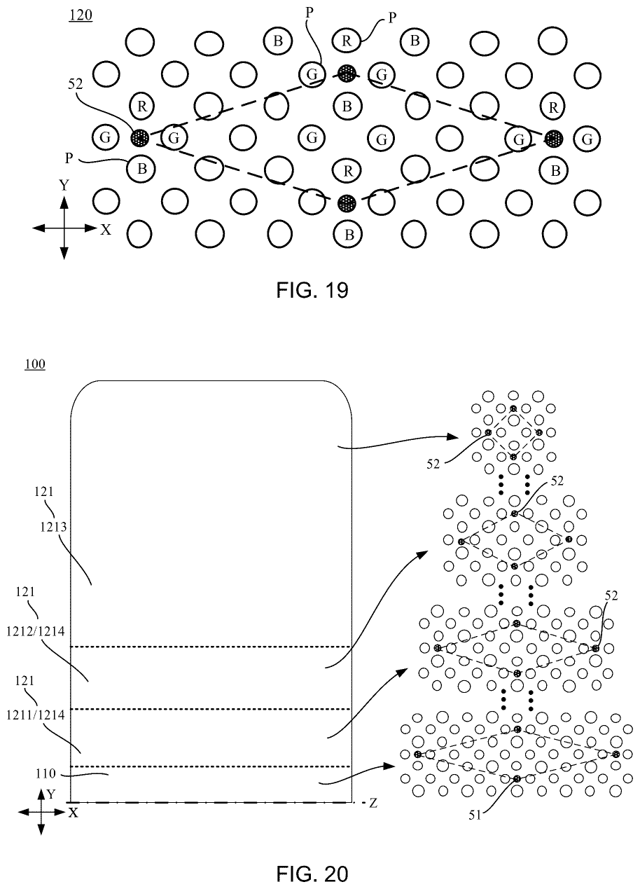

In addition, referring to FIGS. 18 and 19, the density of the second spacers 52 arranged in the first direction X may be less than or equal to the density of the second spacers 52 arranged in the second direction Y.

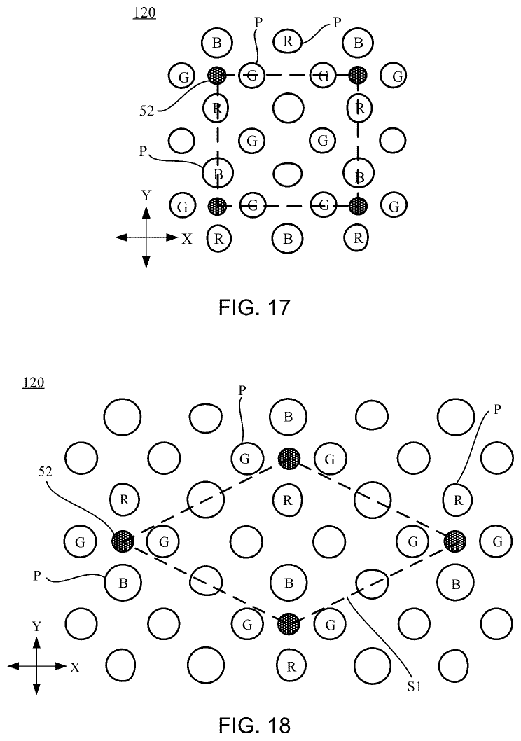

In some examples, referring to FIG. 17, the density of the second spacers 52 arranged in the first direction X is equal to the density of the second spacers 52 arranged in the second direction Y.

For example, referring to FIG. 17, the number of sub-pixels P between any two adjacent second spacers 52 in each row of second spacers 52 is equal to the number of sub-pixels P between any two adjacent second spacers 52 in each column of second spacers 52. The second spacers 52 are evenly arranged, and the support effect on the mask is good, thereby reducing the risk of static electricity release caused by a relatively small distance between the mask and the first electrode 21 (referring to FIG. 7) of the light-emitting device 20 (referring to FIG. 7) below.

For example, as shown in FIG. 17, there are two sub-pixels P between any two adjacent second spacers 52 in each row of second spacers 52, and there are two sub-pixels P between any two adjacent second spacers 52 in each column of second spacers 52.

In some other examples, referring to FIGS. 18 and 19, the density of the second spacers 52 arranged in the first direction X is less to the density of the second spacers 52 arranged in the second direction Y.

It will be understood that although the non-bending portion 120 is a portion of the display panel 100 that is not bent, a portion of the non-bending portion 120 proximate to the bending portion 110 still has a large bending stress, and an edge of the second spacer 52 at the portion of the non-bending portion 120 proximate to the bending portion 110 is still subject to a large compressive stress.

Based on this, by reducing the density of the second spacers 52 arranged in the first direction X and increasing the density of the second spacers 52 arranged in the second direction Y, the number of the second spacers 52 with a relatively great risk of stress release may be reduced in a case where the total density of the second spacers 52 is kept unchanged or slightly reduced, that is, in a case where the second spacers 52 provide a good support for the mask used in the process, thereby reducing stress release points, reducing the risk of cracking of the insulating film layer adjacent to the second spacers 52 (e.g., the first inorganic encapsulation layer 41), reducing the risk of failure of the light-emitting devices 20, and improving product yield.

For example, referring to FIGS. 18 and 19, the number of sub-pixels P between any two adjacent second spacers 52 in each row of second spacers 52 is greater than the number of sub-pixels P between any two adjacent second spacers 52 in each column of second spacers 52. In this way, the number of the second spacers 52 with a relatively great risk of stress release may be greatly reduced, thereby further reducing stress release points, reducing the risk of cracking of the insulating film layer adjacent to the second spacers 52 (e.g., the first inorganic encapsulation layer 41), and improving product yield.

For example, as shown in FIG. 18, there are four sub-pixels P between any two adjacent second spacers 52 in each row of second spacers 52, and there are two sub-pixels P between any two adjacent second spacers 52 in each column of the second spacers 52.

As another example, as shown in FIG. 19, there are six sub-pixels P between any two adjacent second spacers 52 in each row of second spacers 52, and there are two sub-pixels P between any two adjacent second spacers 52 in each column of the second spacers 52.

In some embodiments, referring to FIG. 20, in the second direction Y and from the bending portion 110 to the non-bending portion 120, the non-bending portion 120 includes a plurality of sub-portions 121 connected to each other.

In this case, in the second direction Y and from the bending portion 110 to the non-bending portion 120, bending stresses of the plurality of sub-portions 121 decrease sequentially. That is, the closer the second spacer 52 is to the sub-portion 121 of the bending portion 110, the higher the risk of stress release at an edge of the second spacer 52.

On this basis, in two adjacent sub-portions 121, a sub-portion 121 farther away from the bending portion 110 is a first sub-portion 1211, and a sub-portion 121 closer to the bending portion 110 is a second sub-portion 1212. The density of the second spacers 52 at the first sub-portion 1211 arranged in the first direction X is greater than the density of the second spacers 52 at the adjacent second sub-portion 1212 arranged in the first direction X.

That is, in the second direction Y, the closer to the sub-portion 121 of the bending portion 110, the fewer the second spacers 52 arranged in the first direction X. In this way, the number of the second spacers 52 with a relatively great risk of stress release may be reduced, thereby reducing stress release points, reducing the risk of cracking of the insulating film layer adjacent to the second spacers 52 (e.g., the first inorganic encapsulation layer 41), and improving product yield.

In addition, referring to FIG. 20, the density of the second spacers 52 at the first sub-portion 1211 arranged in the second direction Y is greater than or equal to the density of the second spacers 52 at the adjacent second sub-portion 1212 arranged in the second direction Y.

For example, referring to FIG. 20, in the second direction Y, the density of the second spacers 52 arranged in the second direction Y may also remain unchanged, that is, the density of the second spacers 52 at the first sub-section 1211 arranged in the second direction Y is equal to the density of the second spacers 52 at the adjacent second sub-section 1212 arranged in the second direction Y. In this way, a good support effect on the mask may be provided, thereby reducing the risk of static electricity release caused by a relatively small distance between the mask and the first electrode 21 of the light-emitting device 20 below.

In some embodiments, referring to FIG. 20, a sub-portion 121 farthest away from the bending portion 110 in the plurality of sub-portions 121 is a third sub-portion 1213, and the remaining sub-portions 121 are fourth sub-portions 1214. The third sub-portion 1213 is not subjected to bending stress or is subjected to relatively small bending stress, and the fourth sub-portion 1214 is subjected to relatively large bending stress.

In some examples, referring to FIG. 20, at the third sub-portion 1213, the number of sub-pixels P between any two adjacent second spacers 52 in each row of second spacers 52 is equal to the number of sub-pixels P between any two adjacent second spacers 52 in each column of second spacers 52. In this way, the second spacers 52 are arranged evenly, and may provide a good support for the mask and reduce the risk of static electricity release caused by a relatively small distance between the mask and the first electrode 21 of the light-emitting device 20 below.

In some examples, referring to FIG. 20, at the fourth sub-portion 1214, the number of sub-pixels P between any two adjacent second spacers 52 in each row of second spacers 52 is greater than the number of sub-pixels P between any two adjacent second spacers 52 in each column of second spacers 52.

In this way, by reducing the density of the second spacers 52 arranged in the first direction X and increasing the density of the second spacers 52 arranged in the second direction Y, the number of the second spacers 52 with a relatively great risk of stress release may be reduced in a case where the total density of the second spacers 52 at the fourth sub-portion 1214 is kept unchanged or slightly reduced, thereby reducing stress release points, reducing the risk of cracking of the adjacent insulating film layer (e.g., the first inorganic encapsulation layer 41), reducing the risk of failure of the light-emitting devices 20, and improving product yield.

Based on the fact that the arrangement of the plurality of sub-pixels P is the first arrangement, the second spacers 52 in two adjacent rows may be disposed in a staggered manner or located in the same column.

Some embodiments of the present disclosure will be exemplarily described below by taking an example where there are two sub-pixels P between any two adjacent second spacers 52 in each row of second spacers 52, and there are two sub-pixels P between any two adjacent second spacers 52 in each column of the second spacers 52, but implementations of the present disclosure are not limited thereto.

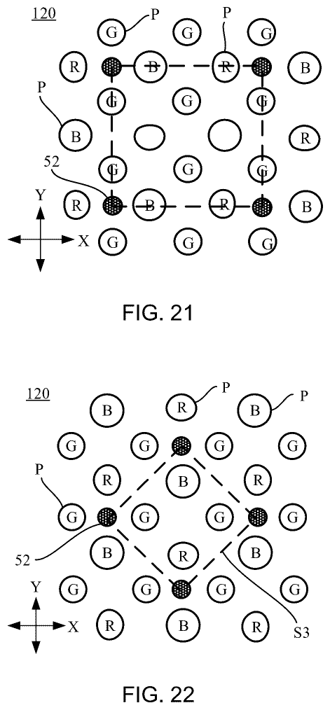

In some embodiments, referring to FIGS. 17 and 21, in two adjacent rows of second spacers 52, any second spacer 52 in a row of second spacers 52 is located in the same column as a second spacer 52 in another row of second spacers 52. That is, four second spacers 52 arranged in two adjacent rows and two adjacent columns constitute a minimum repeating unit, and a line connecting geometric centers of the four second spacers 52 is roughly in a shape of a square.

For example, as shown in FIG. 17, in the first direction X, the second spacer 52 is located between two adjacent green sub-pixels G; in the second direction Y, the second spacer 52 is located between a red sub-pixel R and a blue sub-pixel B that are adjacent. In a case where any second spacer 52 in a row of second spacers 52 is located in the same column as a second spacer 52 in another row of second spacers 52, there is a row of green sub-pixels G between every two adjacent rows of second spacers 52, and there is no second spacer 52 provided between the green sub-pixels G.

For example, as shown in FIG. 21, in the first direction X, the second spacer 52 is located between a red sub-pixel R and a blue sub-pixel B; in the second direction Y, the second spacer 52 is located between two adjacent green sub-pixels G. In a case where any second spacer 52 in a row of second spacers 52 is located in the same column as a second spacer 52 in another row of second spacers 52, there is a row of red sub-pixels R and blue sub-pixels B arranged alternately between every two adjacent rows of second spacers 52, and there is no second spacer 52 provided between the red sub-pixel R and the blue sub-pixel B.

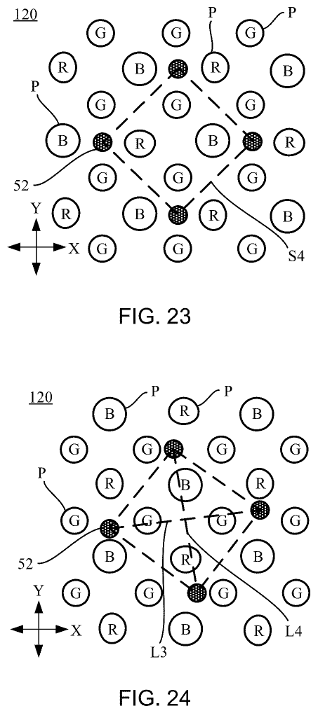

In some other embodiments, referring to FIGS. 22 and 23, in two adjacent rows of second spacers 52, in the first direction X, any second spacer 52 in a row of second spacers 52 is located between two adjacent second spacers 52 in another row of second spacers 52. That is, the two adjacent rows of second spacers 52 are disposed in a staggered manner.

For example, as shown in FIG. 22, in the first direction X, the second spacer 52 is located between two adjacent green sub-pixels G; in the second direction Y, the second spacer 52 is located between a red sub-pixel R and a blue sub-pixel B that are adjacent. In a case where two adjacent rows of second spacers 52 are disposed in a staggered manner, in each row of green sub-pixels G, there is a second spacer 52 provided between two adjacent green sub-pixels G.

On this basis, there are the same number of sub-pixels P between any two second spacers 52 that belong to different rows and are adjacent in the first direction X, so that the force for supporting the mask is dispersed rather evenly, thereby reducing the risk of cracking of the adjacent insulating film layer caused by stress release at the edge of the second spacer 52.

For example, as shown in FIG. 22, in two adjacent rows of second spacers 52, there is a green sub-pixel G between a second spacer 52 in a row of second spacers 52 and each of two second spacers 52 adjacent in the first direction X in another row of second spacers 52.

In a case where a line connecting a geometric center of the second spacer 52 and a geometric center of the adjacent sub-pixel P is approximately parallel to the first direction X or approximately parallel to the second direction Y, geometric centers of two second spacers 52 in a column and geometric centers of two second spacers 52 located between the two second spacers 52 and adjacent to the two second spacers 52 are connected to form a shape, which is a third shape S3, and the third shape S3 is a rhombus. In this way, the force for supporting the mask may further be dispersed rather evenly, thereby further reducing the risk of cracking of the adjacent insulating film layer caused by stress release at the edge of the second spacer 52. It will be noted that an acceptable range of deviation of the approximate parallelism may be, for example, a deviation within 5°.

For example, as shown in FIG. 23, in the first direction X, the second spacer 52 is located between a red sub-pixel R and a blue sub-pixel B that are adjacent; in the second direction Y, the second spacer 52 is located between two adjacent green sub-pixels G. In a case where two adjacent rows of second spacers 52 are disposed in a staggered manner, in each row of red sub-pixels R and blue sub-pixels B arranged alternately, there is a second spacer 52 provided between a red sub-pixel R and a blue sub-pixel B that are adjacent.

On this basis, there are the same number of sub-pixels P between any two second spacers 52 that belong to different rows and are adjacent in the first direction X, so that the force for supporting the mask is dispersed rather evenly, thereby reducing the risk of cracking of the adjacent insulating film layer caused by stress release at the edge of the second spacer 52.

For example, as shown in FIG. 23, in two adjacent rows of second spacers 52, there is a red sub-pixel R and a blue sub-pixel B between a second spacer 52 in a row of second spacers 52 and each of two second spacers 52 adjacent in the first direction X in another row of second spacers 52.

In a case where a line connecting a geometric center of the second spacer 52 and a geometric center of the adjacent sub-pixel P is approximately parallel to the first direction X or approximately parallel to the second direction Y, geometric centers of two second spacers 52 in a column and geometric centers of two second spacers 52 located between the two second spacers 52 and adjacent to the two second spacers 52 are connected to form a shape, which is a fourth shape S4, and the fourth shape S4 is a rhombus. In this way, the force for supporting the mask may further be dispersed rather evenly, thereby further reducing the risk of cracking of the adjacent insulating film layer caused by stress release at the edge of the second spacer 52. It will be noted that an acceptable range of deviation of the approximate parallelism may be, for example, a deviation within 5°.

In some embodiments, referring to FIG. 24, geometric centers of orthographic projections of two adjacent second spacers 52 in the same row on the reference plane are connected to form a third virtual connection line L3, and the third virtual connection line L3 intersects the first direction X. And/or, geometric centers of orthographic projections of two adjacent second spacers 52 in the same column on the reference plane are connected to form a fourth virtual connection line L4, and the fourth virtual connection line L4 intersects the second direction Y.

In this case, in second spacers 52 in the same row and/or the same column, geometric centers of two adjacent second spacers 52 are staggered, so that the supporting force for the supporting mask may be dispersed rather evenly, and thus the second spacers 52 may provide a rather good supporting effect. Moreover, in the second spacers 52 in the same row, the geometric centers of two adjacent second spacers 52 are staggered, and thus the compressive stress applied to the edge of the second spacer 52 during bending may also be reduced, thereby reducing the risk of cracking of the adjacent insulating film layer caused by stress release at the edge of the second spacer 52.

In some embodiments, referring to FIG. 6, the display panel 100 further has a peripheral area B surrounding the display area A, and the peripheral area B includes four frame areas B10 and four corner areas C connecting the four frame areas B10.

The four frame areas B10 include a first frame area B11, a second frame area B12, a third frame area B13 and a fourth frame area B14. In the first direction X, the first frame area B11 and the third frame area B13 are located on opposite sides of the display area A; and in the second direction Y, the second frame area B12 and the fourth frame area B14 are located on opposite sides of the display area A.

On this basis, the display panel 100 further includes a voltage signal line VSS, and the voltage signal line VSS is disposed in the peripheral area B and is configured to transmit a power supply voltage signal.

The voltage signal line VSS may, for example, be made of the same material and located in the same layer as the first electrode 21 of the light-emitting device 20. The second electrode 23 of the light-emitting device 20 may be of a continuous whole-layer structure and extend to the peripheral area B to be connected to the voltage signal line VSS to receive the power supply voltage signal.

For example, referring to FIGS. 6, 25 and 26, an end of the voltage signal line VSS is located in a corner area C at an end of the fourth frame area B14, and another end of the voltage signal line VSS stops in a corner area C at another end of the fourth frame area B14 passing through the first frame area B11, the second frame area B12, the third frame area B13, and corner areas C between the first frame area B11, the second frame area B12 and the third frame area B13. In addition, the pixel defining layer 13 may be, for example, provided with a mesh hollow region 132. The second electrode 23 extends to the peripheral area B and is connected to the voltage signal line VSS through the mesh hollow region 132.

In addition, the voltage signal line VSS may further be provided with a plurality of hollow openings 133 therein to reduce a coverage area of the voltage signal line VSS and an organic layer therebelow. Moreover, a hollow opening 133 may be, for example, located in a grid of the mesh hollow region 132.

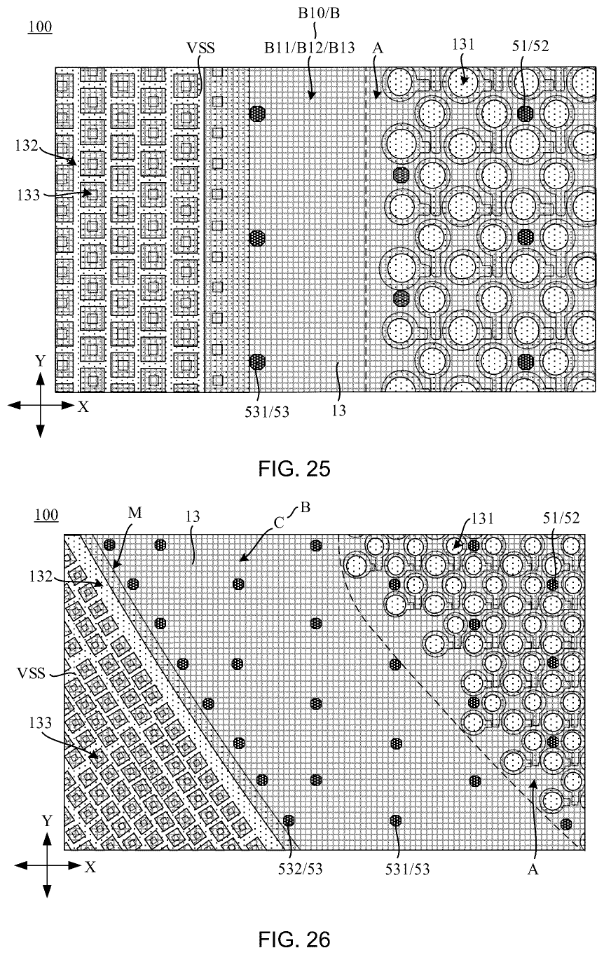

In some embodiments, referring to FIGS. 25 and 26, the display panel 100 further includes a plurality of third spacers 53. The third spacers 53 are disposed in the peripheral area B to support the mask in the peripheral area B, thereby preventing a distance between the mask and the voltage signal line VSS from being excessively small.

In this case, the third spacers 53 support the mask in the peripheral area B, which may reduce the risk of static electricity release of the voltage signal line VSS, thereby reducing the risk of a decreased brightness of display panel 100 caused by an adverse influence on the transmission of the power supply voltage signal due to damage to a surface by static electricity release of the voltage signal line VSS, and reducing the risk of encapsulation failure of the display panel 100 caused by an erosion of the display panel 100 by moisture and oxygen along the cracked gap in the insulating film layer due to crack in an adjacent insulating film layer (e.g., the pixel defining layer 13) caused by static electricity release of the voltage signal line VSS.

It will be understood that in the first frame area B11, the second frame area B12, the third frame area B13 and the four corner areas C, an edge of the mask supported by the spacers 50 is located between two edges of the voltage signal line VSS and the display area A that are close to each other. In the fourth frame area B14, the edge of the mask is roughly flush with an edge of the fourth frame area B14 away from the display area A.

Based on this, in some examples, as shown in FIGS. 6, 25 and 26, in the first frame area B11, the second frame area B12, the third frame area B13 and the four corner areas C, the third spacers 53 are provided between the voltage signal line VSS and the display area A, and may form a good support for the mask. Thus, the materials may be saved, and the costs may be reduced. In the fourth frame area B14, the third spacers 53 are provided between an edge of the display area A and an edge of the fourth frame area B14 to provide a good support for the mask.

In some embodiments, as shown in FIGS. 6, 25 and 26, in any frame area B10 or corner area C, a plurality of third spacers 53 include a plurality of middle spacers 531, and the plurality of middle spacers 531 are arranged in a plurality of rows and a plurality of columns. The plurality of rows of middle spacers 531 each include at least two middle spacers 531 arranged in the first direction X, and the plurality of columns of middle spacers 531 each include at least two middle spacers 531 arranged in the second direction Y. For example, each row of middle spacers 531 includes at least two middle spacers 531 arranged in the first direction X, and each column of middle spacers 531 includes at least two middle spacers 531 arranged in the second direction Y.

In the first frame area B11 and/or the third frame area B13, a row of middle spacers 531 is disposed in the same row as a row of first spacers 51 or a row of second spacers 52; and/or, in the second frame area B12 and/or the fourth frame area B14, a column of middle spacers 531 is disposed in the same column as a column of first spacers 51. With such provision, the middle spacers 531 and the first spacers 51 or the second spacers 52 in the display area A are the same in array, which may simplify the manufacturing process.

In some embodiments, as shown in FIGS. 25 and 26, in at least one frame area B10 or corner area C, the plurality of third spacers 53 further include a plurality of peripheral spacers 532, and the plurality of peripheral spacers 532 are arranged in a row along a target boundary M to provide support for a border of the mask, so as to avoid an excessively small distance between a local region of the mask and the voltage signal line VSS caused by an unsupported local region of the mask proximate to the edge thereof.

In the first frame area B11, the second frame area B12, the third frame area B13 and the four corner areas C, the target boundary M is a boundary of the voltage signal line VSS proximate to the display area A, and in the fourth frame area B14, the target boundary M is a boundary of the fourth frame area B14 away from the display area A.

To avoid the phenomenon of electrostatic discharge generated by the voltage signal line VSS and the local region of the mask caused by the unsupported local region of the mask, a distance between the peripheral spacer 532 and the target boundary M is less than or equal to 130 μm; and/or, a distance between any third spacer 53 and at least one third spacer 53 is less than or equal to 130 μm; and/or, a distance between at least one third spacer 53 and an edge of the display area A is less than or equal to 130 μm. In this case, in the peripheral area B, any circular region of the mask with a diameter of 130 μm is supported by at least one third spacer 53. In this way, it may effectively avoid an increased risk of static electricity release due to an excessively small distance between the local region of the mask and the voltage signal line VSS.

In some embodiments, as shown in FIG. 7, the display panel 100 further includes an anti-reflection film 14, and the anti-reflection film 14 is configured to reduce a reflective intensity of external ambient light on the display panel 100.

In some examples, referring to FIGS. 6 and 7, the anti-reflection film 14 includes a black matrix 141 and color films 142. The black matrix 141 is used to separate light emitted by different sub-pixels P, and has a function of reducing reflected light generated after the external ambient light enters the display panel 100. The color film 142 may filter out light of most wavelength bands in the external ambient light, thereby reducing the reflective intensity of the external ambient light on the display panel 100. In some other examples, the anti-reflection film 14 includes a polarizer, and the polarizer is disposed on a side of the encapsulation layer 40 away from the substrate 11, which is not specifically limited in the embodiments of the present disclosure.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel having a display area, the display panel comprising at least one bending portion, the bending portion being bendable along a bending axis extending in a first direction; and the display panel further comprising:
a plurality of sub-pixels arranged in a plurality of rows and a plurality of columns in the display area, wherein the plurality of rows of sub-pixels each include at least two sub-pixels arranged in the first direction, and the plurality of columns of sub-pixels each include at least two sub-pixels arranged in a second direction; the first direction intersects the second direction; and
a plurality of first spacers disposed between the plurality of sub-pixels and located at the bending portion, wherein the plurality of first spacers are arranged in a plurality of rows and a plurality of columns, the plurality of rows of first spacers each include at least two first spacers arranged in the first direction, and the plurality of columns of first spacers each include at least two first spacers arranged in the second direction; and a density of first spacers arranged in the first direction is less than a density of first spacers arranged in the second direction.

2. The display panel according to claim 1, wherein a number of sub-pixels between any two adjacent first spacers in each row of first spacers is greater than a number of sub-pixels between any two adjacent first spacers in each column of first spacers.

3. The display panel according to claim 2, wherein at least four sub-pixels exist between any two adjacent first spacers in each row of first spacers, and at least two sub-pixels exist between any two adjacent first spacers in each column of first spacers.

4. The display panel according to claim 1, further comprising at least one non-bending portion, the non-bending portionn each being connected to the bending portion; and the display panel further comprising:
a plurality of second spacers disposed between the plurality of sub-pixels and located at the non-bending portion, wherein the plurality of second spacers are arranged in a plurality of rows and a plurality of columns, the plurality of rows of second spacers each include at least two second spacers arranged in the first direction, and the plurality of columns of second spacers each include at least two second spacers arranged in the second direction; and a density of second spacers arranged in the first direction is less than or equal to a density of second spacers arranged in the second direction; wherein
the density of the second spacers arranged in the first direction is greater than the density of the first spacers arranged in the first direction; and/or the density of the second spacers arranged in the second direction is greater than or equal to the density of the first spacers arranged in the second direction.

5. The display panel according to claim 4, wherein a number of sub-pixels between any two adjacent second spacers in each row of second spacers is equal to a number of sub-pixels between any two adjacent second spacers in each column of second spacers.

6. The display panel according to claim 4, wherein in the second direction and from a bending portion to a non-bending portion, the non-bending portion includes a plurality of sub-portions connected to each other;
in two adjacent sub-portions, a sub-portion farther away from the bending portion is a first sub-portion, and a sub-portion closer to the bending portion is a second sub-portion; and
a density of second spacers at the first sub-portion arranged in the first direction is greater than a density of second spacers at an adjacent second sub-portion arranged in the first direction; and/or a density of second spacers at the first sub-portion arranged in the second direction is greater than or equal to a density of second spacers at the adjacent second sub-portion arranged in the second direction.

7. The display panel according to claim 6, wherein a sub-portion farthest away from the bending portion in the plurality of sub-portions is a third sub-portion, and remaining sub-portions are fourth sub-portions;
at the third sub-portion, a number of sub-pixels between any two adjacent second spacers in each row of second spacers is equal to a number of sub-pixels between any two adjacent second spacers in each column of second spacers;
and/or, at a fourth sub-portion, a number of sub-pixels between any two adjacent second spacers in each row of second spacers is greater than a number of sub-pixels between any two adjacent second spacers in each column of second spacers.

8. The display panel according to claim 1, wherein the plurality of sub-pixels includes a plurality of red sub-pixels, a plurality of green sub-pixels and a plurality of blue sub-pixels;
the plurality of red sub-pixels and the plurality of blue sub-pixels are arranged in an array of multiple rows and multiple columns, each row of red sub-pixels and blue sub-pixels includes multiple red sub-pixels and multiple blue sub-pixels that are arranged alternately in the first direction, and each column of red sub-pixels and blue sub-pixels includes multiple red sub-pixels and multiple blue sub-pixels that are arranged alternately in the second direction; and
the plurality of green sub-pixels are arranged in an array of multiple rows and multiple columns, and a green sub-pixel is disposed between red sub-pixels and blue sub-pixels in each two rows and two columns arranged adjacent to each other.

9. The display panel according to claim 8, wherein in two adjacent rows of first spacers, any first spacer in a row of first spacers is located between two adjacent first spacers in another row of first spacers.

10. The display panel according to claim 9, wherein sub-pixels existing between any two first spacers that belong to different rows and are adjacent in the first direction have a same number.

11. The display panel according to claim 8, further comprising a plurality of second spacers, wherein in two adjacent rows of second spacers, any second spacer in a row of second spacers is located between two adjacent second spacers in another row of second spacers.

12. The display panel according to claim 11, wherein sub-pixels existing between any two second spacers that belong to different rows and are adjacent in the first direction have a same number.

13. The display panel according to claim 1, wherein geometric centers of orthographic projections of two adjacent first spacers in a same row on a reference plane are connected to form a first virtual connection line, and the first virtual connection line intersects the first direction; the reference plane is a plane defined by the first direction and the second direction;
and/or, geometric centers of orthographic projections of two adjacent first spacers in a same column on the reference plane are connected to form a second virtual connection line, and the second virtual connection line intersects the second direction.

14. The display panel according to claim 1, futher comprising a plurality of second spacers, wherein geometric centers of orthographic projections of two adjacent second spacers in a same row on a reference plane are connected to form a third virtual connection line, and the third virtual connection line intersects the first direction; the reference plane is a plane determined by the first direction and the second direction;
and/or, geometric centers of orthographic projections of two adjacent second spacers in a same column on the reference plane are connected to form a fourth virtual connection line, and the fourth virtual connection line intersects the second direction.

15. The display panel according to claim 1, further having a peripheral area surrounding the display area, wherein the peripheral area includes four frame areas and four corner areas connecting the four frame areas; the four frame areas include a first frame area, a second frame area, a third frame area and a fourth frame area; in the first direction, the first frame area and the third frame area are located on opposite sides of the display area; and in the second direction, the second frame area and the fourth frame area are located on opposite sides of the display area;
the display panel further comprising:
a voltage signal line, wherein an end of the voltage signal line is located in a corner area at an end of the fourth frame area, and another end of the voltage signal line stops in a corner area at another end of the fourth frame area passing through the first frame area, the second frame area, the third frame area, and corner areas between the first frame area, the second frame area and the third frame area; and
a plurality of third spacers disposed in the peripheral area, wherein in the first frame area, the second frame area, the third frame area and the four corner areas, third spacers are disposed between the voltage signal line and the display area; and in the fourth frame area, third spacers are disposed between an edge of the display area and an edge of the fourth frame area.

16. The display panel according to claim 15, wherein in any frame area or corner area, the plurality of third spacers include a plurality of middle spacers; the plurality of middle spacers are arranged in a plurality of rows and a plurality of columns, the plurality of rows of middle spacers each include at least two middle spacers arranged in the first direction, and the plurality of columns of middle spacers each include at least two middle spacers arranged in the second direction; and
in the first frame area and/or the third frame area, a row of middle spacers is disposed in a same row as a row of first spacers or a row of second spacers; and/or, in the second frame area and/or the fourth frame area, a column of middle spacers is disposed in a same column as a column of first spacers.

17. The display panel according to claim 16, wherein in at least one frame area or corner area, the plurality of third spacers further include a plurality of peripheral spacers, and the plurality of peripheral spacers are arranged in a row along a target boundary; and
in the first frame area, the second frame area, the third frame area and the four corner areas, the target boundary is a boundary of the voltage signal line proximate to the display area; and in the fourth frame area, the target boundary is a boundary of the fourth frame area away from the display area.

18. The display panel according to claim 17, wherein a distance between a peripheral spacer and the target boundary is less than or equal to 130 μm.

19. The display panel according to claim 15, wherein a distance between any third spacer and at least one third spacer is less than or equal to 130 μm; and/or a distance between at least one third spacer and an edge of the display area is less than or equal to 130 μm.

20. A display device, comprising:
the display panel according to claim 1; and
a circuit board connected to the display panel.
